(19) United States
(12) Patent Application Publication
(10) Pub. No.: US 2017/0198395 A1
(43) Pub. Date: Jul. 13, 2017

(54) PLASMA PROCESSING APPARATUS

(71) Applicant: TOKYO ELECTRON LIMITED, Tokyo (JP)

(72) Inventor: Toshihisa NOZAWA, Miyagi (JP)

(73) Assignee: TOKYO ELECTRON LIMITED, Tokyo (JP)

(21) Appl. No.: 15/326,078

(22) PCT Filed: Jun. 19, 2015
(86) PCT No.: PCT/JP2015/067688

§ 371 Date: Jan. 13, 2017

(30) Foreign Application Priority Data
Jul. 15, 2014 (JP) 2014-145186

(51) Int. Cl. C23C 16/511; H01L 21/02; C23C 16/34; H01L 21/67; C23C 16/458; C23C 16/46; H01L 21/3065; H01L 21/687

(52) U.S. Cl. CPC C23C 16/511; H01L 21/3065; H01L 21/02274; H01L 21/68742; H01L 21/67069; H01L 21/0217; C23C 16/4584; C23C 16/463; C23C 16/345

(57) ABSTRACT

A plasma processing apparatus includes a processing chamber that air-tightly accommodates a substrate; a microwave supply unit that radiates microwaves into the processing chamber; a processing gas supply unit that supplies a processing gas into the processing chamber; and a substrate holding mechanism that holds the substrate within the processing chamber. A support shaft vertically passes through the bottom surface of the processing chamber to support the bottom surface of the substrate holding mechanism, and a rotary driving mechanism is provided outside the processing chamber to rotate the support shaft. In addition, a magnetic fluid seal air-tightly closes a gap between the support shaft and the processing chamber, and a choke mechanism is provided above the magnetic fluid seal to suppress the magnetic fluid seal from being heated by leakage of microwaves from the gap between the support shaft and the processing chamber.

### CROSS-REFERENCE OF RELATED APPLICATION

This application is based on and claims priority from Japanese Patent Application No. 2014-145186 filed on Jul. 15, 2014 with Japan Patent Office, the disclosure of which is incorporated herein.

The present disclosure relates to a plasma processing apparatus that turns a processing gas supplied into a processing chamber, into plasma by microwaves, to process a workpiece.

### BACKGROUND ART

As a plasma processing apparatus that performs a predetermined plasma processing on a workpiece such as, for example, a semiconductor wafer (hereinafter, referred to as a “wafer”), a plasma processing apparatus that generates plasma by radiating microwaves into a processing chamber has been conventionally known. In the plasma processing apparatus using microwaves, high-density plasma with a low electron temperature may be generated within a processing chamber, and for example, a film forming process or an etching process is performed by the generated plasma.

The above described plasma processing apparatus includes, for example, a placing table provided within the processing chamber, a heating mechanism configured to heat the placing table, an exhaust mechanism configured to exhaust the inside of the processing chamber, a microwave supply unit configured to radiate microwaves into the processing chamber, and a gas supply unit configured to supply a predetermined processing gas.

In such a plasma processing apparatus, a distribution of the processing gas or a distribution of the plasma within the processing chamber influences the in-plane uniformity of a processing on the wafer. Therefore, for example, as disclosed in Patent Document 1, in order to uniformize the flow of the processing gas within the processing chamber, a baffle plate having a plurality of exhaust holes is disposed around a placing table, or in order to perform a uniform plasma processing, a focus ring that converges the plasma on the wafer is disposed in the vicinity of an outer peripheral portion of the wafer.

### PRIOR ART DOCUMENT

### Patent Document

Patent Document 1: Japanese Patent Laid-Open Publication No. 2010-118549

### SUMMARY OF INVENTION

### Problems to be Solved

However, since microwaves are highly directive, an intensity distribution of the radiated microwaves varies due to, for example, slight protrusions or depressions on a propagation path of the microwaves, or an assembly error of a microwave supply unit. Therefore, it is very difficult to ensure the uniformity of the intensity distribution particularly in a circumferential direction of the wafer.

Also, in the above described adjustment using the baffle plate or the focus ring, there is still a limitation in suppressing the variation of the intensity distribution of the microwaves.

The present disclosure has been made in view of this point, and an object thereof is to provide a microwave plasma processing apparatus that performs a wafer processing with in-plane uniformity even when an intensity distribution of microwaves varies particularly in a circumferential direction of a wafer.

### Means for Solving the Problems

In order to achieve the above described object, the present disclosure provides a plasma processing apparatus that processes a substrate with microwave plasma. The plasma processing apparatus includes: a processing chamber that air-tightly accommodates the substrate; a microwave supply unit that radiates microwaves into the processing chamber; a processing gas supply unit that supplies a processing gas into the processing chamber; a substrate holding mechanism that holds the substrate within the processing chamber; a support shaft that vertically passes through a bottom surface of the processing chamber to support a bottom surface of the substrate holding mechanism; a rotary driving mechanism that is provided outside the processing chamber to rotate the support shaft; a magnetic fluid seal that air-tightly closes a gap between the support shaft and the processing chamber; and a choke mechanism that is provided above the magnetic fluid seal to suppress the magnetic fluid seal from being heated by leakage of the microwaves from the gap between the support shaft and the processing chamber.

The inventor has got an idea that in order to perform a processing with in-plane uniformity on a substrate, averaging variations of an intensity distribution of microwaves by positively rotating, for example, the substrate within the processing chamber is effective in addition to uniformizing microwaves radiated into a processing chamber or uniformizing a flow of a processing gas within the processing chamber by, for example, a baffle plate. The present disclosure is based on this idea, and a support shaft supporting a substrate holding mechanism may be rotated by a rotary driving mechanism so as to rotate the substrate held by the substrate holding mechanism during a plasma processing. Accordingly, even when a variation occurs in the intensity distribution of microwaves radiated into the processing chamber, a substrate processing with in-plane uniformity may be performed.

Also, the rotary driving mechanism such as, for example, a motor needs to be disposed outside the processing chamber. Thus, it is necessary to provide the support shaft supporting the substrate holding mechanism, through the processing chamber. In such a case, there occur problems such as maintenance of air-tightness of the processing chamber or a leakage of microwaves from a gap between the support shaft and the processing chamber. However, according to the present disclosure, since there are provided a magnetic fluid seal that air-tightly closes a gap between the support shaft and the processing chamber and a choke mechanism that prevents a leakage of the microwaves from the gap between the support shaft and the processing chamber, the inside of the processing chamber can be kept in a vacuum state, and the leakage of the microwaves to the outside of the processing chamber can be suppressed to a minimum. Also, since the choke mechanism is provided above the magnetic fluid seal, the magnetic fluid seal can be suppressed from being heated by the leakage of the microwaves, and exceeding, for example, a heat resistant temperature of the magnetic fluid seal. Therefore, the inside of the processing chamber can be reliably kept air-tight.

### Effect of the Invention

According to the present disclosure, in a microwave plasma processing apparatus, a wafer processing with in-plane uniformity may be performed even when an intensity distribution of microwaves varies particularly in a circumferential direction of a wafer.

### BRIEF DESCRIPTION OF DRAWINGS

FIG. 1 is a vertical sectional view illustrating a schematic configuration of a plasma processing apparatus according to an exemplary embodiment.

FIG. 2 is a vertical sectional view illustrating a schematic configuration in the vicinity of a rotary seal mechanism.

FIG. 3 is a vertical sectional view illustrating a schematic configuration of a plasma processing apparatus according to another exemplary embodiment.

FIG. 4 is a vertical sectional view illustrating a schematic configuration of a plasma processing apparatus according to another exemplary embodiment.

FIG. 5 is a vertical sectional view illustrating a schematic configuration of a plasma processing apparatus according to another exemplary embodiment.

FIG. 6 is a vertical sectional view illustrating a schematic configuration of a plasma processing apparatus according to another exemplary embodiment.

FIG. 7 is an explanatory view illustrating a schematic configuration of a lift arm according to another exemplary embodiment.

FIG. 8 is a plan view illustrating a schematic configuration of another lift arm.

### DETAILED DESCRIPTION OF THE INVENTION

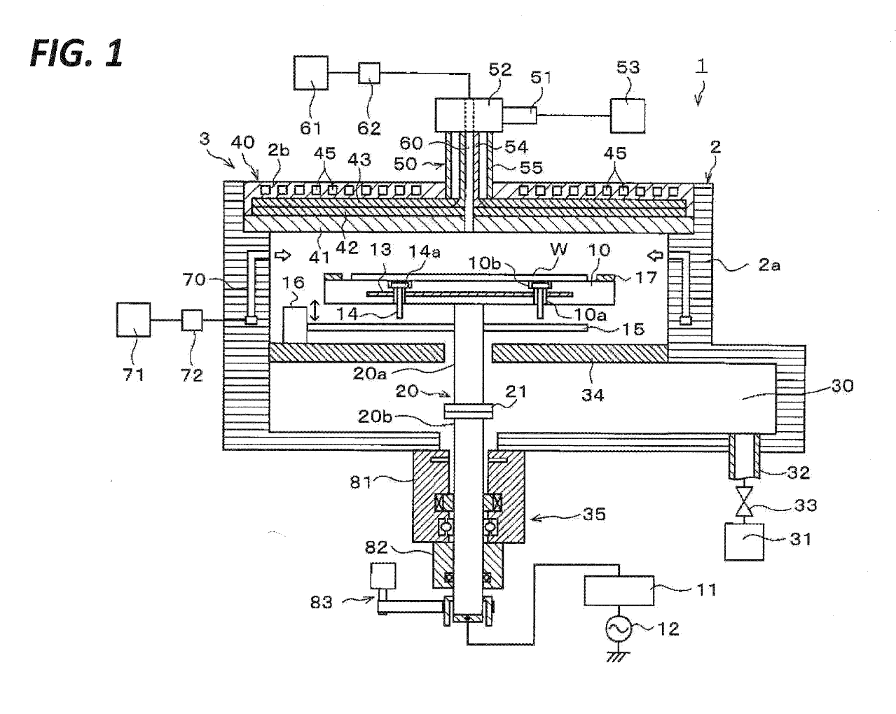

Hereinafter, an exemplary embodiment of the present disclosure will be described. FIG. 1 is a vertical sectional view illustrating a schematic configuration of a plasma processing apparatus 1 according to an exemplary embodiment. Meanwhile, in the present exemplary embodiment, descriptions will be made on, as an example, a case where a plasma chemical vapor deposition (CVD) processing is performed on a surface of a wafer W by the plasma processing apparatus 1, thereby forming, for example, an SiN film (silicon nitride film), on the surface of the wafer W. Also, in the present specification and drawings, components having substantially the same functional configurations will be denoted by the same symbols, and the redundant descriptions thereof will be omitted.

The plasma processing apparatus 1 includes a processing chamber 2 having an air-tightly maintained interior, and a microwave supply unit 3 configured to radiate microwaves into the processing chamber 2. The processing chamber 2 includes a substantially cylindrical body portion 2a with a top side opened, and a substantially disk-shaped cover 2b that air-tightly closes the opening of the body portion 2a. The body portion 2a and the cover 2b are made of a metal such as, for example, aluminum. Also, the body portion 2a is grounded by a ground wire (not illustrated).

A susceptor 10 is provided within the processing chamber 2, as a substrate holding mechanism configured to hold a wafer W. The susceptor 10 has, for example, a disk shape, and is made of a metal such as, for example, aluminum. A high-frequency power source 12 for bias is connected to the susceptor 10 via a matcher 11 through a slip ring 100 to be described below. The high-frequency power source 12 outputs high frequency waves at a predetermined frequency (e.g., 13.56 MHz) suitable for controlling the energy of ions to be attracted to the wafer W. Meanwhile, although not illustrated, an electrostatic chuck is provided in the susceptor 10 to electrostatically attract the wafer W so that the wafer W is electrostatically attracted onto the susceptor 10. Also, a heater 13 is provided within the susceptor 10 to heat the wafer W to a predetermined temperature. The supply of an electric power to the heater 13 is also performed through the slip ring 100 to be described below.

Meanwhile, an elevating pin 14 is provided below the susceptor 10 to support the wafer W from below and raise and lower the wafer W. The elevating pin 14 is inserted into a through hole 10a vertically passing through the susceptor 10 so as to be movable with respect to the susceptor 10, and is also formed to be longer than the thickness of the susceptor 10 so as to protrude from the top surface of the susceptor 10. A lift arm 15 is provided below the elevating pin 14 to push up the elevating pin 14. The lift arm 15 is configured to be movable up and down by an elevating mechanism 16. The elevating pin 14 is not connected to the lift arm 15. When the lift arm 15 is lowered, the elevating pin 14 and the lift arm 15 are separated from each other. The upper end portion 14a of the elevating pin 14 has a larger diameter than the through hole 10a. Therefore, even when the lift arm 15 is retracted downward, the elevating pin 14 does not fall off from the through hole 10a and is engaged with the susceptor 10. Also, a recessed portion 10b larger in a diameter and a thickness than the upper end portion 14a of the elevating pin 14 is formed at the upper end of the through hole 10a, so that the upper end portion 14a does not protrude from the top surface of the susceptor 10 in a state where the elevating pin 14 is engaged with the susceptor 10. Meanwhile, FIG. 1 illustrates a state where the lift arm 15 is lowered such that the elevating pin 14 is engaged with the susceptor 10.

An annular focus ring 17 is provided to surround the wafer W on the top surface of the susceptor 10. For the focus ring 17, an insulating material such as, for example, ceramics or quartz is used. Plasma generated within the processing chamber 2 is converged on the wafer W by the action of the focus ring 17, thereby improving the in-plane uniformity of a plasma processing on the wafer W.

The center portion of the bottom surface of the susceptor 10 is supported by, for example, a cylindrical support shaft 20 having a hollow center portion. The support shaft 20 extends vertically downwards, and is provided to vertically pass through the bottom surface of the body portion 2a of the processing chamber 2. The support shaft 20 includes an upper shaft 20a that abuts on the susceptor 10, and a lower shaft 20b connected to the upper shaft 20a through a flange 21 formed at the lower end of the upper shaft 20a. The upper shaft 20a and the lower shaft 20b are made of, for example, an insulating member.

An exhaust chamber 30 is formed in the bottom portion of the body portion 2a of the processing chamber 2 to laterally protrude from, for example, the body portion 2a. An exhaust mechanism 31 is connected to the bottom surface of the exhaust chamber 30 through an exhaust pipe 32 to exhaust the inside of the processing chamber 2. A regulation valve 33 is provided in the exhaust pipe 32 to regulate an exhaust amount caused by the exhaust mechanism 31.

An annular baffle plate 34 configured to uniformly exhaust the inside of the processing chamber 2 is provided above the exhaust chamber 30 and below the susceptor 10 to be spaced apart from the outer surface of the support shaft 20 by a predetermined gap. An opening (not illustrated) that passes through the baffle plate 34 in the thickness direction is formed over the entire circumference of the baffle plate 34.

A rotary seal mechanism 35 is provided at the lower end face of the bottom portion of the body portion 2a of the processing chamber 2, that is, at the outside of the processing chamber 2 to air-tightly close the gap between the support shaft 20 and the body portion 2a, and also to rotate the support shaft 20 around the vertical axis. Details of the rotary seal mechanism 35 will be described below.

The microwave supply unit 3 is provided at an opening portion of a ceiling surface of the processing chamber 2 to supply microwaves for generating plasma. The microwave supply unit 3 includes a radial line slot antenna 40. The radial line slot antenna 40 includes a microwave transmitting plate 41, a slot plate 42, and a slow wave plate 43. The microwave transmitting plate 41, the slot plate 42, and the slow wave plate 43 are stacked from the bottom in this order, and are provided at an opening portion of the body portion 2a of the processing chamber 2. The top surface of the slow wave plate 43 is covered with the cover 2b. Meanwhile, the radial line slot antenna 40 is disposed at a position where its center substantially coincides with the rotation center of the support shaft 20.

The gap between the microwave transmitting plate 41 and the body portion 2a is kept air-tight by a sealing material (not illustrated) such as, for example, an O-ring. For the microwave transmitting plate 41, a dielectric such as, for example, quartz, Al₂O₃, or AlN is used, and the microwave transmitting plate 41 transmits microwaves.

A plurality of slots are formed in the slot plate 42 provided on the top surface of the microwave transmitting plate 41, and the slot plate 42 serves as an antenna. For the slot plate 42, a conductive material such as, for example, copper, aluminum, or nickel is used.

The slow wave plate 43 provided on the top surface of the slot plate 42 is made of a low loss dielectric material such as, for example, quartz, Al₂O₃, or AlN, and shortens the wavelength of microwaves.

Within the cover 2b covering the top surface of the slow wave plate 43, a plurality of annular flow paths 45 are formed through which, for example, a cooling medium is circulated. The cover 2b, the microwave transmitting plate 41, the slot plate 42, and the slow wave plate 43 are adjusted to a predetermined temperature by the cooling medium flowing through the flow paths 45.

A coaxial waveguide 50 is connected to the central portion of the cover 2b. A microwave generating source 53 is connected to the upper end portion of the coaxial waveguide 50 via a rectangular waveguide 51 and a mode converter 52. The microwave generating source 53 is provided outside the processing chamber 2, and may generate microwaves of, for example, 2.45 GHz.

The coaxial waveguide 50 includes an inner conductor 54 and an outer tube 55. The inner conductor 54 is connected to the slot plate 42. The inner conductor 54 on the side of the slot plate 42 is formed in a conical shape so as to efficiently propagate the microwaves to the slot plate 42.

Through such a configuration, the microwaves generated from the microwave generating source 53 sequentially propagate through insides of the rectangular waveguide 51, the mode converter 52, and the coaxial waveguide 50, and are compressed by the slow wave plate 43 to be shortened in the wavelength. Then, circularly polarized microwaves are transmitted through the microwave transmitting plate 41 from the slot plate 42 and radiated into the processing chamber 2. By the microwaves, a processing gas is turned into plasma within the processing chamber 2, and the wafer W is subjected to a plasma processing by the plasma.

A first processing gas supply pipe 60 is provided in the central portion of the ceiling surface of the processing chamber 2, that is, in the central portion of the radial line slot antenna 40. The first processing gas supply pipe 60 passes through the radial line slot antenna 40 in the vertical direction, and one end portion of the first processing gas supply pipe 60 is opened at the bottom surface of the microwave transmitting plate 41. Also, the first processing gas supply pipe 60 passes through the inside of the inner conductor 54 of the coaxial waveguide 50 and further is inserted into the mode converter 52. The other end portion of the first processing gas supply pipe 60 is connected to a first processing gas supply source 61.

The first processing gas supply source 61 is configured to individually supply, for example, trisilylamine (TSA), N₂ gas, H₂ gas, and Ar gas, respectively, as processing gases. Among them, TSA, N₂ gas, and H₂ gas are raw material gases for forming a SiN film, and Ar gas is a gas for plasma excitation. Hereinafter, the processing gas may be referred to as a “first processing gas.” Also, a supply device group 62 including, for example, a valve or a flow rate regulator that controls the flow of the first processing gas is provided in the first processing gas supply pipe 60. The first processing gas supplied from the first processing gas supply source 61 is supplied into the processing chamber 2 through the first processing gas supply pipe 60, and flows vertically downwards toward the wafer W placed on the susceptor 10.

Also, as illustrated in FIG. 1, a second processing gas supply pipe 70 is provided in the inner peripheral surface at the upper portion of the processing chamber 2. A plurality of second processing gas supply pipes 70 are provided along the inner peripheral surface of the processing chamber 2 at equal intervals. A second processing gas supply source 71 is connected to the second processing gas supply pipes 70. The second processing gas supply source 71 is configured to individually supply, for example, trisilylamine (TSA), N₂ gas, H₂ gas, and Ar gas, respectively, as processing gases from the inside of the second processing gas supply source 71. Meanwhile, hereinafter, the processing gas may be referred to as a “second processing gas.” Also, a supply device group 72 including, for example, a valve or a flow rate regulator that controls the flow of the second processing gas is provided in the second processing gas supply source 71. The second processing gas supplied from the second processing gas supply source 71 is supplied into the processing chamber 2 through the second processing gas supply pipes 70, and flows toward the outer peripheral portion of the wafer W placed on the susceptor 10. In this manner, the first processing gas is supplied from the first processing gas supply pipe 60 toward the central portion of the wafer W, and the second processing gas is supplied from the second processing gas supply pipes 70 toward the outer peripheral portion of the wafer W.

Meanwhile, the processing gases supplied from the first processing gas supply pipe 60 and the second processing gas supply pipes 70 into the processing chamber 2, respectively, may be the same type of gases or different types of gases, and may be supplied at independent flow rates, respectively, or at an arbitrary flow rate ratio.

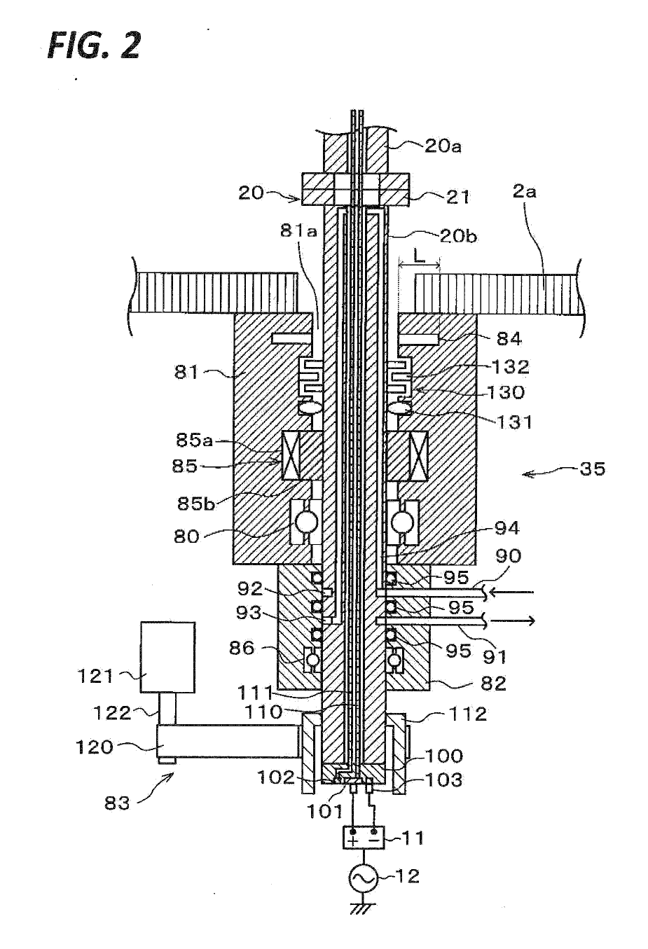

Hereinafter, the rotary seal mechanism 35 will be described in detail. FIG. 2 is a vertical sectional view illustrating a schematic configuration of the rotary seal mechanism 35. The rotary seal mechanism 35 includes a casing 81 that holds the support shaft 20 via a bearing 80, a rotary joint 82 connected to the lower end of the casing, and a rotary driving mechanism 83 that rotates the support shaft 20.

The casing 81 includes an opening 81a having an inner diameter larger than an outer diameter of the support shaft 20, and the lower shaft 20b of the support shaft 20 is inserted into the opening 81a. The upper end portion of the casing 81 is fixed to the bottom portion of the body portion 2a of the processing chamber 2 by, for example, a bolt (not illustrated), and a gap between the upper end portion of the casing 81 and the lower end face of the body portion 2a is kept air-tight by, for example, an O-ring (not illustrated).

A choke 84 is annularly provided over the entire circumference of the inner peripheral surface at the upper portion of the casing 81 to suppress leakage of microwaves from a gap between the lower shaft 20b and the casing 81. The choke 84 is formed into a slit shape having, for example, a rectangular cross section. Meanwhile, the length L of the choke 84 is set to be a length of approximately ¼ of the wavelength of microwaves for the purpose of preventing leakage of the microwaves. Meanwhile, when, for example, a dielectric is filled within the choke 84, the length L of the choke 84 does not necessarily have to be ¼ of the wavelength of the microwaves.

A magnetic fluid seal 85 is provided as a sealing member that air-tightly closes the gap between the lower shaft 20b of the support shaft 20 and the casing 81, below the choke 84 on the inner peripheral surface of the casing 81. The magnetic fluid seal 85 is constituted by, for example, an annular permanent magnet 85a embedded in the casing 81, and a magnetic fluid 85b enclosed between the permanent magnet 85a and the lower shaft 20b. A gap between the support shaft 20 and the processing chamber 2 is kept air-tight by the magnetic fluid seal 85.

The bearing 80 is provided below the magnetic fluid seal 85 in the support shaft 20. The bearing 80 is supported by the casing 81. Accordingly, the support shaft 20 is supported to be rotatable with respect to the casing 81. Meanwhile, in FIG. 2, only a bearing in a radial direction is illustrated, but a thrust bearing that supports a vertical load may be provided, as necessary.

The rotary joint 82 having an annular shape is connected to the lower end of the casing 81. The rotary joint 82 is connected to the lower shaft 20b via a bearing 86, and the lower shaft 20b is rotatable with respect to the rotary joint 82. A coolant supply pipe 90 is connected to the side surface of the rotary joint 82, and a coolant discharge pipe 91 is connected below, for example, the coolant supply pipe 90. On the outer peripheral surface of the lower shaft 20b, annular grooves 92 and 93 are formed at positions corresponding to the coolant supply pipe 90 and the coolant discharge pipe 91, respectively. A coolant supply passage 94 is formed within the lower shaft 20b to communicate with the groove 92 and to extend vertically upwards. The coolant supply passage 94 extends to the vicinity of the flange 21 and is folded back vertically downwards from the vicinity of the flange 21 to be connected to the groove 93. A coolant supply source (not illustrated) is connected to the coolant supply pipe 90, and the coolant supplied from the coolant supply source cools the flange 21 through the coolant supply pipe 90 and the coolant supply passage 94, and then is discharged from the coolant discharge pipe 91.

O-rings 95 are provided on the upper and lower sides of the inner peripheral surface of the rotary joint 82 so that the grooves 92 and 93 are sandwiched. Therefore, the coolant is supplied to the coolant supply passage 94 without leaking from the gap between the rotary joint 82 and the lower shaft 20b.

The slip ring 100 having a cylindrical shape is connected to, for example, the lower end face of the lower shaft 20b. A disk-shaped rotating electrode 101 is provided at the central portion of the lower end face of the slip ring 100, and for example, an annular rotating electrode 102 is provided outside the rotating electrode 101. Conductive wires 110 and 111 are electrically connected to the rotating electrodes 101 and 102, respectively, to supply a high-frequency power to the susceptor 10 from the high-frequency power source 12 or feed a power to the heater within the susceptor 10. The conductive wires 110 and 111 are provided to extend upwards along the hollow portion within the support shaft 20 and are connected to the susceptor 10. When a power is fed to the conductive wires 110 and 111, for example, as illustrated in FIG. 2, a power source is connected to the rotating electrodes 101 and 102 through a brush 103. The brush 103 is fixed by, for example, a fixing member (not illustrated) so that, for example, the relative positional relationship with respect to the body portion 2a of the processing chamber 2 is not changed. Meanwhile, FIG. 2 illustrates a state where the matcher 11 and the high-frequency power source 12 are connected to the rotating electrodes 101 and 102 through the brush 103. However, for example, the arrangement of rotating electrodes or the number of provided rotating electrodes is not limited to the contents of the present exemplary embodiment, and may be arbitrarily set. Examples of devices to be connected to the rotating electrodes may include a power source that supplies a power to the heater 13, a power source that applies a voltage to the electrostatic chuck, or a thermocouple used for controlling a temperature of the heater 13 and embedded in the susceptor 10.

A shielding member 112 formed in a cylindrical shape surrounding the slip ring 100 is fixed to, for example, the lower shaft 20b below the rotary joint 82. The shielding member 112 is made of, for example, an insulating member, and is configured such that, for example, a contact portion between the slip ring 100 and the brush 103 is not exposed.

Also, a belt 120 is connected to the outer peripheral portion of the shielding member 112. A motor 121 is connected to the belt 120 via a shaft 122. Accordingly, when the motor 121 is rotated, the shielding member 112 is rotated through the shaft 122 and the belt 120, and then the support shaft 20 fixed to the shielding member 112 is rotated. The rotary driving mechanism 83 according to the present disclosure is constituted with the shielding member 112, the belt 120, and the motor 121. When the support shaft 20 is rotated, the slip ring 100 is also rotated, but the electrical connection with the rotating electrodes 101 and 102 is maintained by the brush 103. Also, the coolant supply passage 94 formed within the lower shaft 20b is also rotated by rotation of the support shaft 20, but a connection with the coolant supply pipe 90 and the coolant discharge pipe 91 is maintained through the grooves 92 and 93 formed in the lower shaft 20b. Thus, even when the support shaft 20 is rotated, the supply of the coolant to the coolant supply passage 94 is maintained.

Meanwhile, in FIG. 2, the rotary joint 82 and the rotary driving mechanism 83 are provided in this order below the casing 81. However, the arrangement or shape of the rotary joint 82 and the rotary driving mechanism 83 may be arbitrarily set as long as the support shaft 20 may be properly rotated by the rotary driving mechanism 83. Also, the configuration of the rotary driving mechanism 83 is not limited to the contents of the present exemplary embodiment, and the arrangement of the motor 121 or a mechanism that transfers a driving force of the motor 121 to the support shaft 20 may be arbitrarily set.

The plasma processing apparatus 1 according to the present exemplary embodiment is configured as described above. Hereinafter, a plasma processing performed on a wafer W by the plasma processing apparatus 1 according to the present exemplary embodiment will be described. In the present exemplary embodiment, a plasma film forming process is performed on the wafer W as described above to form a SiN film on the surface of the wafer W.

In the processing of the wafer W, first, a gate valve (not illustrated) provided in the processing chamber 2 is opened, and the wafer W is carried into the processing chamber 2. The wafer W is delivered to the elevating pin 14, and then, the elevating mechanism 16 is lowered so that the wafer W is placed on the susceptor 10. At the same time, a DC voltage is applied to the electrostatic chuck, and the wafer W is electrostatically attracted onto the susceptor 10 by a Coulomb force. Then, after the gate valve is closed to hermetically seal the inside of the processing chamber 2, the exhaust mechanism 31 is operated to reduce the pressure of the inside of the processing chamber 2 to a predetermined pressure, e.g., 400 mTorr (=53 Pa). Also, the motor 121 is rotated so that the susceptor 10 is rotated through the support shaft 20. Here, since the elevating pin 14 is provided separately from the lift arm 15, the elevating pin 14 is rotated together with the susceptor 10.

Thereafter, the first processing gas is supplied into the processing chamber 2 from the first processing gas supply pipe 60, and the second processing gas is supplied into the processing chamber 2 from the second processing gas supply pipes 70. Here, the flow rate of Ar gas supplied from the first processing gas supply pipe 60 is, for example, 100 sccm (mL/min), and the flow rate of Ar gas supplied from the second processing gas supply pipes 70 is, for example, 750 sccm (mL/min).

The first processing gas and the second processing gas are supplied into the processing chamber 2, and the microwave generating source 53 is operated to generate microwaves of a predetermined power at a frequency of, for example, 2.45 GHz. The microwaves are radiated into the processing chamber 2 through the rectangular waveguide 51, the mode converter 52, the coaxial waveguide 50, and the radial line slot antenna 40. Within the processing chamber 2, the processing gas is turned into plasma by the microwaves, the processing gas is dissociated in the plasma, and a film forming process is performed on the wafer W by radicals (active species) generated at that time. Here, since the wafer W is rotated within the processing chamber 2 according to the rotation of the susceptor 10, even when, for example, an electric field intensity distribution of the microwaves radiated from the radial line slot antenna 40 is not uniform, a plasma processing may be averaged in the plane of the wafer W and may be uniformly performed in the plane. Thus, a SiN film is formed on the surface of the wafer W.

While the plasma film forming process is performed on the wafer W, high frequency waves of a predetermined power are applied to the susceptor 10 at a frequency of, for example, 13.56 MHz by the high-frequency power source 12. The application of an RF bias within an appropriate range causes ions in the plasma to be attracted to the wafer W, thereby improving the denseness of the SiN film, and increasing traps in the film. Also, since the electron temperature of the plasma may be kept low by using the microwave plasma, there is no damage to the film. Also, since the molecules of the processing gas may be easily dissociated by the high density plasma, the reaction is promoted.

Thereafter, when the SiN film is grown so that a predetermined film thickness of SiN film is formed on the wafer W, the radiation of the processing gas and the microwaves is stopped. Then, the wafer W is carried out from the processing chamber 2, and a series of plasma film forming processes are terminated.

According to the exemplary embodiment described above, the support shaft 20 supporting the susceptor 10 may be rotated by the rotary driving mechanism 83 having the motor 121 or the belt 120 so as to rotate the wafer W held by the susceptor 10 during the plasma processing. Accordingly, even when an intensity distribution of microwaves radiated into the processing chamber 2 varies, a wafer processing with in-plane uniformity may be performed.

Also, the rotary driving mechanism 83 needs to be disposed outside the processing chamber 2 in order to avoid exposure to plasma, and thus it is necessary to provide the support shaft 20 through the processing chamber 2. In such a case, in order to maintain the air-tightness of the processing chamber 2, providing, for example, an O-ring in a sliding portion between the support shaft 20 and the processing chamber 2 may be considered. However, particles may be generated in the O-ring and the sliding portion of the support shaft 20, thereby contaminating the wafer W. In this respect, the magnetic fluid 85b as a sealing member may be used as in the present disclosure, so that an air-tightness between the support shaft 20 and the processing chamber 2 may be maintained and also an occurrence of particles may be suppressed.

Also, the magnetic fluid 85b easily absorbs microwaves. When the magnetic fluid 85b is exposed to microwaves, the temperature of the magnetic fluid 85b may rise, thereby exceeding a heat resistant temperature (about 150° C.). Meanwhile, as in the present exemplary embodiment, the choke 84 that suppresses leakage of microwaves from a gap between the support shaft 20 and the processing chamber 2 is provided above the magnetic fluid seal 85, thereby suppressing the leakage of the microwaves from the processing chamber 2 to the outside, and greatly reducing the microwaves reaching the magnetic fluid 85b. As a result, the magnetic fluid 85b may be suppressed from being heated beyond the heat resistant temperature, and also the inside of the processing chamber 2 may be kept air-tight.

Meanwhile, from the viewpoint of keeping the inside of the processing chamber 2 air-tight, it is not denied to use, for example, an O-ring as a sealing member. For example, according to allowable particles, an O-ring may be used as a sealing member instead of the magnetic fluid seal 85. Also, from the viewpoint of reducing microwaves or radicals reaching the magnetic fluid seal 85, for example, a seal mechanism 130 may be provided as a second sealing member between the choke 84 and the magnetic fluid seal 85 as illustrated in FIG. 2. The seal mechanism 130 includes, for example, an O-ring 131 provided below the choke 84, and a labyrinth seal 132 provided between the choke 84 and the O-ring 131 and configured to reduce a differential pressure acting on the O-ring 131. Since the air-tightness between the processing chamber 2 and the support shaft 20 is secured by the magnetic fluid seal 85, a sealing performance against a gas is not required for the O-ring 131, and it is desirable to use, for example, polytetrafluoroethylene (PTFE) that is highly resistant against sliding or friction and also resistant against radicals generated within the processing chamber 2.

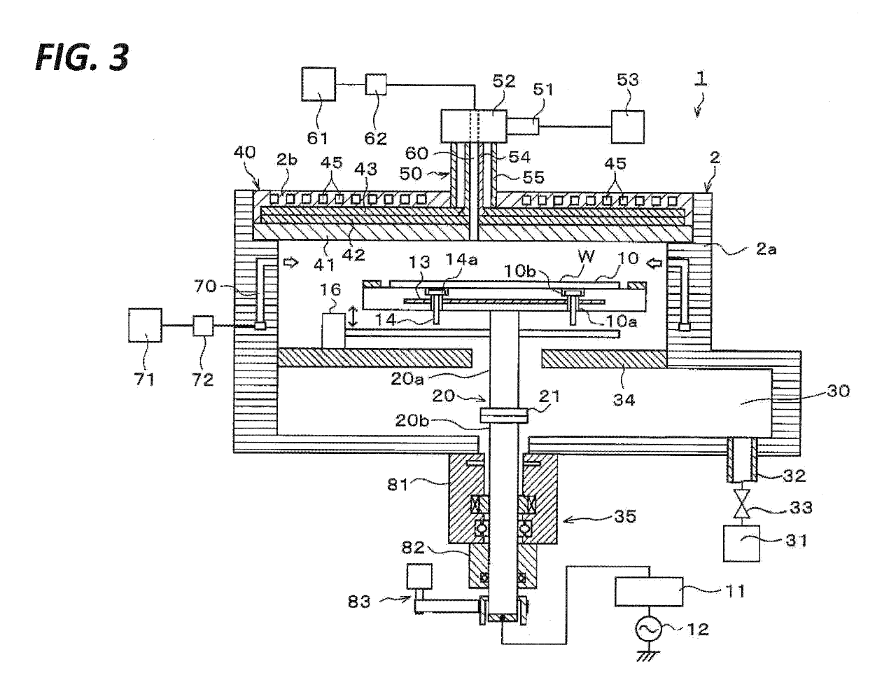

In the above described exemplary embodiment, the rotation center of the support shaft 20 substantially coincides with the center of the radial line slot antenna 40 (the radiation center of the microwaves). However, as illustrated in FIG. 3, for example, the rotation center of the support shaft 20 may be eccentric with respect to the center of the radial line slot antenna 40 in plan view.

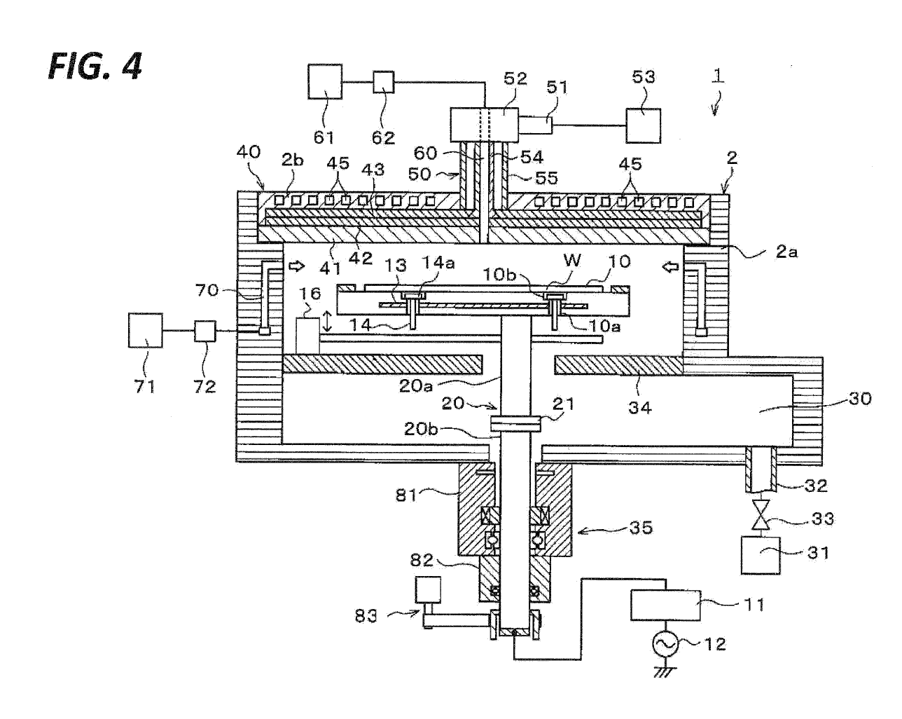

In general, the intensity distribution of microwaves varies in the circumferential direction and the intensity tends to be gradually reduced from, for example, the radiation center of the microwaves toward the outer peripheral portion. That is, according to the diameter direction of the wafer W, the intensity distribution of the microwaves varies. Therefore, for example, as illustrated in FIG. 3, when the rotation center of the support shaft 20 is eccentric with respect to the center of the radial line slot antenna 40, a variation of the intensity of the microwaves along the diameter direction of the wafer W may be made uniform and also a plasma processing with in-plane uniformity may be performed. Meanwhile, in FIG. 3, the center of the susceptor 10 coincides with the center of the support shaft 20, in other words, the rotation center of the wafer W coincides with the rotation center of the support shaft 20. However, for example, as illustrated in FIG. 4, the center of the susceptor 10 and the center of the radial line slot antenna 40 may be located at the corresponding positions, and the support shaft 20 may be connected to a position eccentric with respect to the center of the susceptor 10.

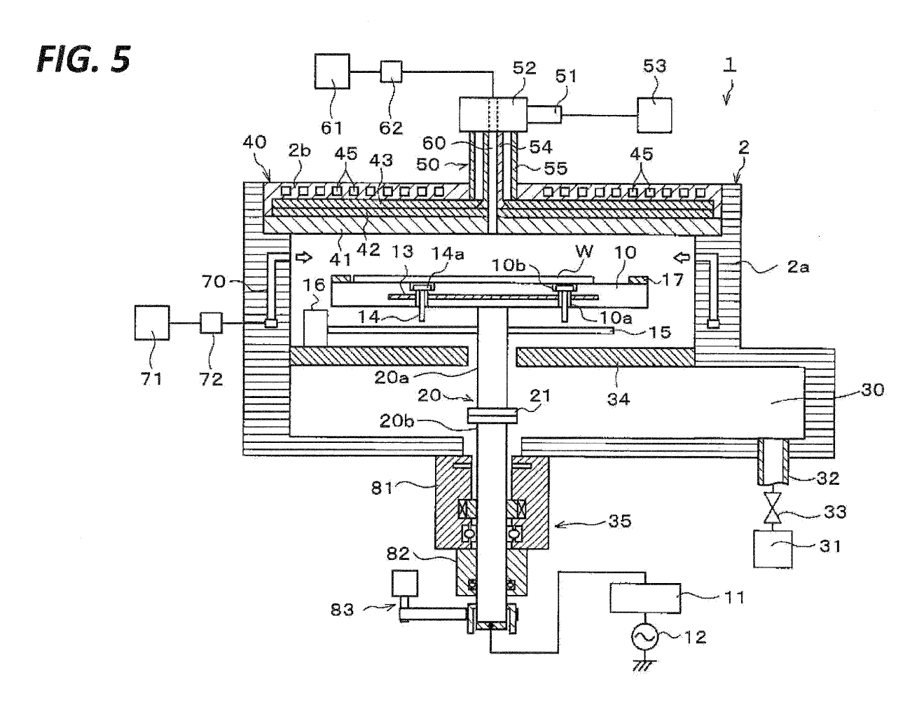

Also, the rotation center of the support shaft 20 may not be shifted from the center of the radial line slot antenna 40, but, for example, as illustrated in FIG. 5, the center of the wafer W may be disposed at a position eccentric with respect to the center of the susceptor 10 such that the rotation center of the wafer W may be eccentric with respect to the radiation center of the microwaves when the susceptor 10 is rotated.

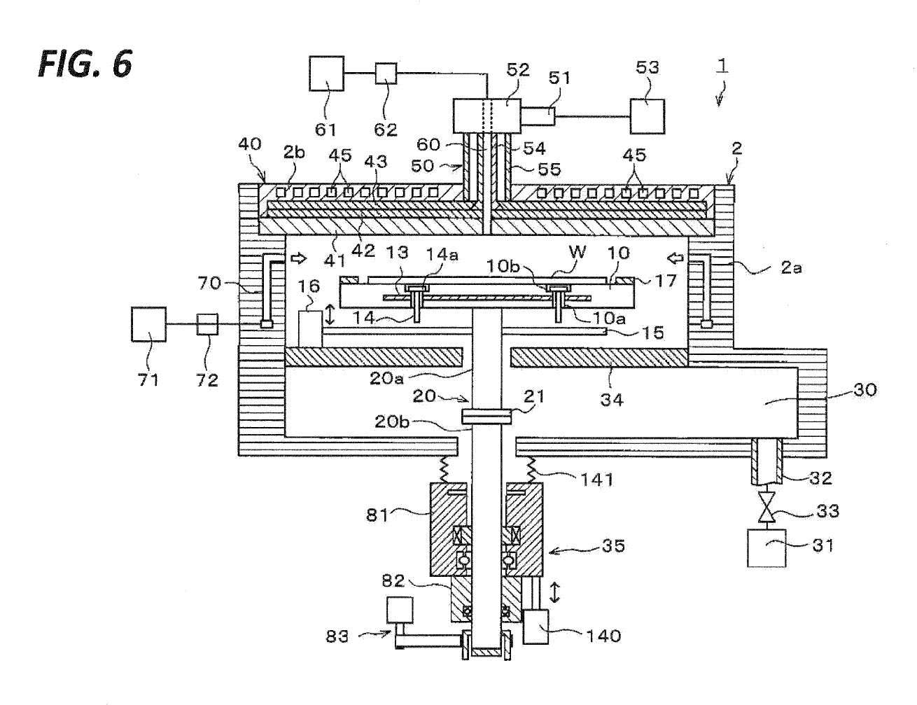

Meanwhile, from the viewpoint of averaging the intensity distribution of microwaves, particularly, the intensity distribution along the diameter direction, as illustrated in FIG. 6, an elevating mechanism 140 may be provided to raise and lower the susceptor 10. In such a case, there may be proposed a structure in which, for example, a bellows 141 air-tightly connected to the body portion 2a and the casing 81 is provided between the lower end face of the body portion 2a and the upper end face of the casing 81 such that, for example, the susceptor 10, together with the casing 81 and the support shaft 20, is raised and lowered by the elevating mechanism 140. When the susceptor 10 is raised and lowered, the intensity distribution of the microwaves along the diameter direction of the wafer W, which may not be completely averaged by only the rotating operation of the susceptor 10, may be averaged, thereby more uniformly performing a plasma processing of the wafer W.

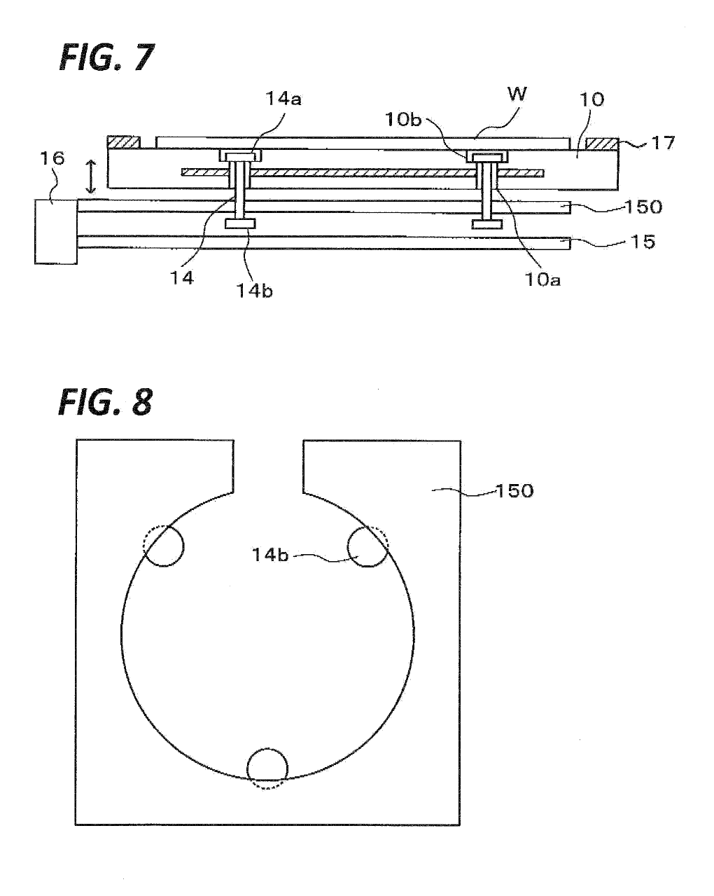

In the above described exemplary embodiment, the lift arm 15 and the elevating pin 14 are provided separately. However, even when the lift arm 15 is lowered, the elevating pin 14 may not be separated from the wafer W due to charging to the wafer W by an electrostatic chuck. In such a case, for example, as illustrated in FIG. 7, another lift arm 150 may be provided above the lift arm 15 and spaced apart from the lift arm 15 by a predetermined distance, so that the elevating pin 14 may be separated from the wafer W by the other lift arm 150. In such a case, for example, as illustrated in FIG. 7, a lower end portion 14b of the elevating pin 14 is formed as an engaging portion thicker than an outer diameter of the elevating pin 14, and as illustrated in FIG. 8, the other lift arm 150 is formed to be engaged with the lower end portion 14b of the elevating pin 14. Then, when the elevating pin 14 is raised, the lift arm 15 pushes up the lower end portion 14b of the elevating pin 14, thereby raising the elevating pin 14. When the elevating pin 14 is lowered, the lower end portion 14b is engaged with the bottom surface of the other lift min 150, and in this state, the other lift arm 150 is lowered, thereby pushing down the elevating pin 14. As a result, even when the wafer W is charged, the elevating pin 14 may be separated from the wafer W. Meanwhile, the lift aim 15 and the other lift arm 150 may operate in synchronization with each other or may operate individually.

Although the exemplary embodiments of the present disclosure have been described above with reference to accompanying drawings, the present disclosure is not limited to such exemplary embodiments. It will be apparent to those skilled in the art that various modified or changed examples may be conceived within the scope of the spirit described in claims, and naturally fall within the technical scope of the present disclosure. Also, in the exemplary embodiments described above, the present disclosure is applied to a plasma processing for performing a film forming process, but may also be applied to a plasma processing for performing a substrate processing, e.g., an etching process or a sputtering process, other than the film forming process. Also, a workpiece to be processed by the plasma processing of the present disclosure may be any one of, for example, a glass substrate, a glass EL substrate, and a substrate for a flat panel display (FPD).

### INDUSTRIAL APPLICABILITY

The present disclosure is useful for a plasma processing on, for example, a semiconductor wafer, and particularly for a plasma processing using microwaves.

Explanation of Reference Numerals

| | |
|---|---|
| 1: plasma processing apparatus | 2: processing chamber |
| 3: microwave supply unit | 10: susceptor |
| 11: matcher | 12: high-frequency power source |
| 13: heater | 14: elevating pin |
| 15: lift arm | 16: elevating mechanism |
| 17: focus ring | 20: support shaft |
| 21: flange | 30: exhaust chamber |
| 31: exhaust mechanism | 32: exhaust pipe |
| 33: regulation valve | 34: baffle plate |
| 35: rotary seal mechanism | 40: radial line slot antenna |
| 41: microwave transmitting plate | 42: slot plate |
| 43: slow wave plate | 50: coaxial waveguide |
| 60: first processing gas | 70: second processing gas supply pipe |
| supply pipe | |
| 80: bearing | 81: casing |
| 82: rotary joint | 83: rotary driving mechanism |
| 84: choke | 85: magnetic fluid seal |
| W: wafer | |

What is claimed is:

1. A plasma processing apparatus that processes a substrate with microwave plasma, the plasma processing apparatus comprising:
a processing chamber that air-tightly accommodates the substrate;
a microwave supply unit that radiates microwaves into the processing chamber;
a processing gas supply unit that supplies a processing gas into the processing chamber;
a substrate holding mechanism that holds the substrate within the processing chamber;
a support shaft that vertically passes through a bottom surface of the processing chamber to support a bottom surface of the substrate holding mechanism;
a rotary driving mechanism that is provided outside the processing chamber to rotate the support shaft;
a magnetic fluid seal that air-tightly closes a gap between the support shaft and the processing chamber; and
a choke mechanism that is provided above the magnetic fluid seal to suppress the magnetic fluid seal from being heated by leakage of the microwaves from the gap between the support shaft and the processing chamber.

2. The plasma processing apparatus of claim 1, further comprising:
a sealing member provided between the magnetic fluid seal and the choke mechanism to shield radicals.

3. The plasma processing apparatus of claim 1, wherein the support shaft includes therein a coolant flow path through which a coolant supplied from a coolant supply mechanism provided outside the processing chamber is circulated, and
the coolant flow path and the coolant supply mechanism are connected via a rotary joint.

4. The plasma processing apparatus of claim 1, wherein the substrate holding mechanism includes a heater configured to heat the substrate,
the support shaft includes therein a conductive wire to supply a current to the heater, and
the conductive wire is connected with a power source via a slip ring to supply a current to the heater.

5. The plasma processing apparatus of claim 1, wherein at least one of a rotation center of the support shaft and a center of the substrate is located at a position eccentric with respect to a radiation center of the microwaves from the microwave supply unit in plan view.

6. The plasma processing apparatus of claim 1, further comprising:
an elevating pin vertically inserted into the substrate holding mechanism and provided to be movable with respect to the substrate holding mechanism; and
an elevating mechanism that raises and lowers the elevating pin,
wherein the elevating mechanism includes a first lift arm that pushes up the elevating pin, and a second lift arm that pushes down the elevating pin,
the elevating pin is formed to be longer than a thickness of the substrate holding mechanism, and
the elevating pin includes an engaging portion formed at a lower end portion thereof to be engaged with the second lift arm when the elevating pin is pushed down by the second lift arm.
